(19) United States
(12) Patent Application Publication
(10) Pub. No.: US 2025/0364211 A1
(43) Pub. Date: Nov. 27, 2025

(54) SYSTEM AND METHOD FOR PLASMA PROCESS

(71) Applicant: Tokyo Electron Limited, Tokyo (JP)

(72) Inventors: Joel Blakeney, Austin, TX (US); Zhiying Chen, Austin, TX (US); Megan Carruth, Austin, TX (US)

(21) Appl. No.: 18/674,483

(22) Filed: May 24, 2024

(51) Int. Cl. H01J 37/32; H01L 21/26

(52) U.S. Cl. CPC H01J 37/32146; H01L 21/26

(57) ABSTRACT

A method for plasma processing includes providing a substrate into a plasma processing chamber, generating a plasma in the plasma processing chamber by providing source power to a top electrode of the plasma processing chamber, and biasing a bottom electrode of the plasma processing chamber by providing a waveform voltage to the bottom electrode. The waveform voltage includes: a discharge step including multiple sinusoidal pulses, and a biasing step including a negative linear slope.

### TECHNICAL FIELD

The present invention relates generally to plasma processing, and, in particular embodiments, to plasma processing methods, apparatuses, and systems.

### BACKGROUND

Device formation within microelectronic workpieces can involve a series of manufacturing techniques including formation, patterning, and removal of a number of layers of material on a substrate. In order to achieve the physical and electrical specifications of current and next generation semiconductor devices, processing flows enabling reduction of feature size while maintaining structural integrity is desirable for various patterning processes. As device structures densify and develop vertically, the desire for precision material processing becomes more compelling.

Plasma processes are commonly used to form devices, interconnects, and contacts in microelectronic workpieces. For example, plasma etching and plasma deposition are common process steps during semiconductor device fabrication. A combination of source power (SP) applied to a coupling element and bias power (BP) applied to a substrate holder can be used to generate and direct plasma. Various conditions during a plasma process may influence whether material is being deposited onto a substrate, etched from the substrate, or a combination of the two.

### SUMMARY

In accordance with an embodiment, a method for plasma processing includes: providing a substrate into a plasma processing chamber; generating a plasma in the plasma processing chamber by providing source power to a top electrode of the plasma processing chamber; and biasing a bottom electrode of the plasma processing chamber by providing a waveform voltage to the bottom electrode, the waveform voltage including: a discharge step including multiple sinusoidal pulses; and a biasing step including a negative linear slope.

In accordance with another embodiment, a method for producing a bias waveform includes: discharging a substrate disposed on a substrate holder by operating a radio frequency (RF) amplifier of a pulser circuit for a set number of cycles, the RF amplifier being coupled with the substrate holder; floating a linear amplifier of the pulser circuit to a voltage provided by the RF amplifier; opening a first switch coupled between the RF amplifier and the substrate holder and closing a second switch coupled between an output terminal of the linear amplifier and the substrate holder; and controlling an output of the linear amplifier with feedback from an ion flux sensor, the ion flux sensor being coupled with the substrate holder.

In accordance with yet another embodiment, a pulser circuit includes: a radio frequency (RF) amplifier; a first switch, a first terminal of the first switch being coupled to the RF amplifier, a second terminal of the first switch being coupled with a substrate holder through a first node and a second node; a linear amplifier including a negative input terminal, a positive input terminal, and an output terminal, the negative input terminal being coupled through a second switch to the first node, the output terminal being coupled through a third switch to the second node; and a master timing circuit configured to open and close the first switch, the second switch, and the third switch.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B illustrate graphs of bias waveforms, in accordance with some embodiments;

FIG. 2 illustrates a plasma processing system, in accordance with some embodiments;

FIG. 3 illustrates a graph of compensation current of a pulser circuit versus measured ion flux, in accordance with some embodiments;

FIGS. 4 through 8 illustrate diagrams of the pulser circuit 200 at various stages of operation, in accordance with some embodiments;

FIG. 9 illustrates a process flow chart diagram of a method for plasma processing, in accordance with some embodiments; and

FIG. 10 illustrates a process flow chart diagram of a method for producing a bias waveform, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

While inventive aspects are described primarily in the context of radiating structures in a plasma processing system, the inventive aspects may be similarly applicable to fields outside the semiconductor industry. Plasma can be used to treat and modify surface properties through functional group addition. For example, to treat surfaces for paint deposit, plasma can convert hydrophobic surfaces to hydrophilic surfaces. Further, the inventive aspects are not limited to plasma. For example, RF can be used to thaw out frozen food or dry out textiles, food, wood, or the like.

Both source power (SP) and bias power (BP) may be supplied as radio frequency (RF) power to the processing chamber of a plasma processing apparatus. Pulsed plasma processing methods supply one or both of the RF source power and RF bias power to a processing chamber as pulses rather than as continuous wave power. For example, in some embodiments BP pulses may be provided synchronously or asynchronously with SP pulses. In other embodiments, BP pulses are provided with continuous wave SP.

For some plasma processes such as atomic layer etching (ALE) or the like, bias waveforms (also referred to as bias voltage waveforms) may be applied to substrates (e.g., semiconductor wafers) to determine ion energy distribution at the substrate surface, thereby controlling anisotropy and selectivity of the etch process. Bias waveforms may include a charge cycle (also referred to as a biasing cycle) in which the waveform achieves a negative value in order to accelerate ions to the substrate surface and a discharge cycle in which the waveform acquires a positive value to attract electrons and neutralize charge accumulation from ions. Bias waveform types include RF biasing (in other words, sinusoidal wave biasing), pulse-shaped biasing (in other words, square wave biasing), and tailored waveform biasing. A tailored waveform biasing may include negative current slope to compensate for ion charge accumulation, thereby yielding a constant substrate voltage.

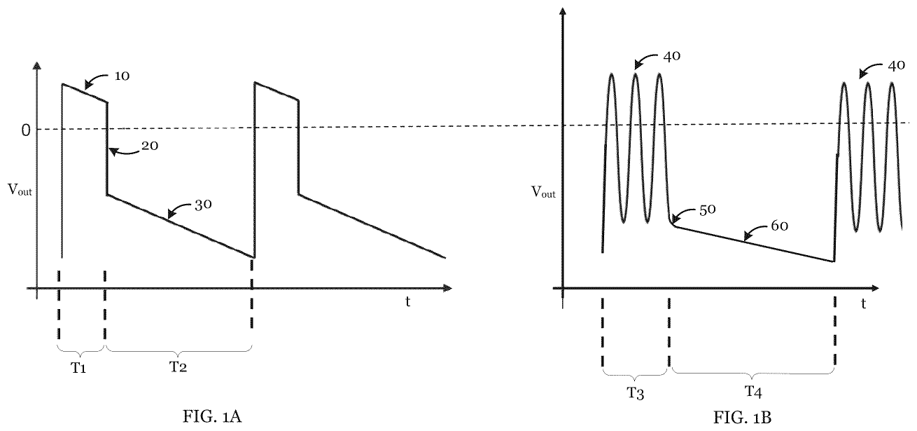

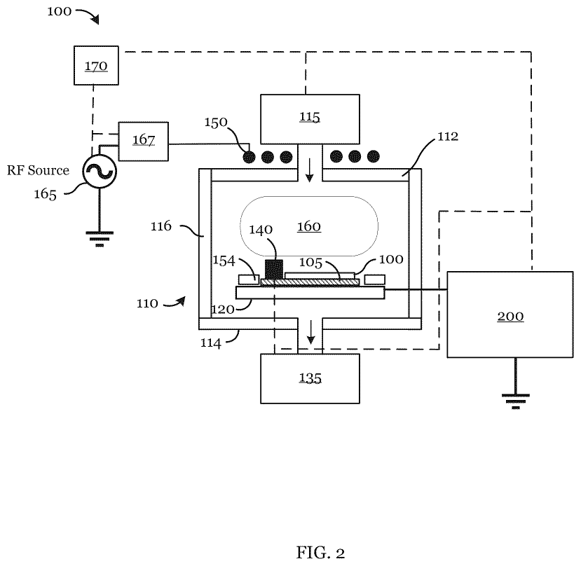

Tailored waveforms (also referred to as bias waveforms or waveform voltages) may be produced with specialized power supplies. For example, a voltage supply and a current supply may be used to realize the waveform over three steps and obtain a narrow ion energy distribution function (IEDF). FIG. 1A illustrates an example bias waveform with a voltage reversal step 10, a regulation step 20, and a compensation step 30. The voltage reversal step 10 and the regulation step 20 may be controlled by the voltage supply and the compensation step 30 may be controlled by the current supply. The voltage reversal step 10 creates a positive electric potential on a substrate (e.g., the substrate 102, which may be a wafer; see below, FIG. 2) to which the tailored waveform is applied. The regulation step 20 then regulates the desired potential at the substrate surface by decreasing it by a voltage Vₛₜₑₚ. The compensation step 30 is regulated by a separate current supply that supplies an increasing amount of current (also referred to as a compensation current I_{comp}). This compensates for the increasing amount of positive charge on the substrate surface from ion flux. An advantageous result is a constant voltage potential at the substrate surface during the compensation step 30. This may allow for a narrow, single peak ion energy distribution function, with the ion energy at the peak being proportional to

$${V}_{step} * \frac{{C}_{C h u c k}}{{C}_{C h u c k} + {C}_{S h e a t h}} ,$$

where C_{Chuck} is the capacitance of the substrate holder 105 and C_{Sheath} is the sheath capacitance of the plasma 160. Increased selectivity of ion energy in an atomic layer etching (ALE) energy process window may be enabled by controlling the voltage Vₛₜₑₚ.

According to one or more embodiments of the present disclosure, this application relates to methods, apparatuses, and systems for tailored bias waveforms. Next generation nodes, including three-dimensional structures, are increasing demand for improved control over etch ion energies and ion angular distributions. Ion energy and angle distributions may be significantly influenced by sheath voltage distributions on wafers during plasma processing. As such, herein is disclosed a bias pulser (also referred to as a tailored waveform pulser) using current and voltage sources that allows for precise control of wafer sheath voltage. This is advantageous for improving etch rate by increased material selectability and ion flux through high aspect structures.

The tailored waveform pulser (also referred to as a pulser circuit or a tailored bias waveform pulser circuit) may be implemented with voltage and current sources mediated by a high voltage (HV) switch that separates discharge and charge regions of the pulser circuit. The discharge region comprises a radio frequency (RF) bias source which may discharge the substrate surface and determine the wafer potential for etching processes (in other words, the etch energy). The charge region comprises a linear amplifier that is floated to the potential of the RF bias source. The linear amplifier may be a linear voltage amplifier, linear current amplifier, high voltage function generator, the like, or a combination thereof. The tailored waveform pulser can generate a constant sheath voltage energy providing improved energy selectivity, such as for atomic layer etching (ALE) processes. The constant sheath voltage may improve ion angular distribution, which is advantageous for improving throughput in, for example, high aspect ratio processes and for reducing aspect ratio dependent etching (ARDE) effects. Additionally, the energy consumption of the tailored waveform pulser is significantly reduced in comparison with other methods of tailored waveform generation, which is advantageous for reducing cost and achieving lower greenhouse gas emissions.

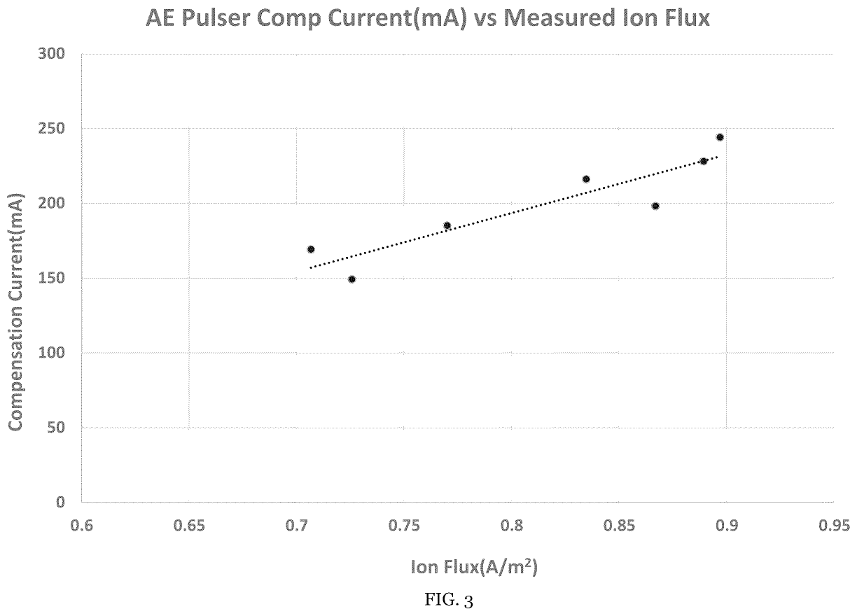

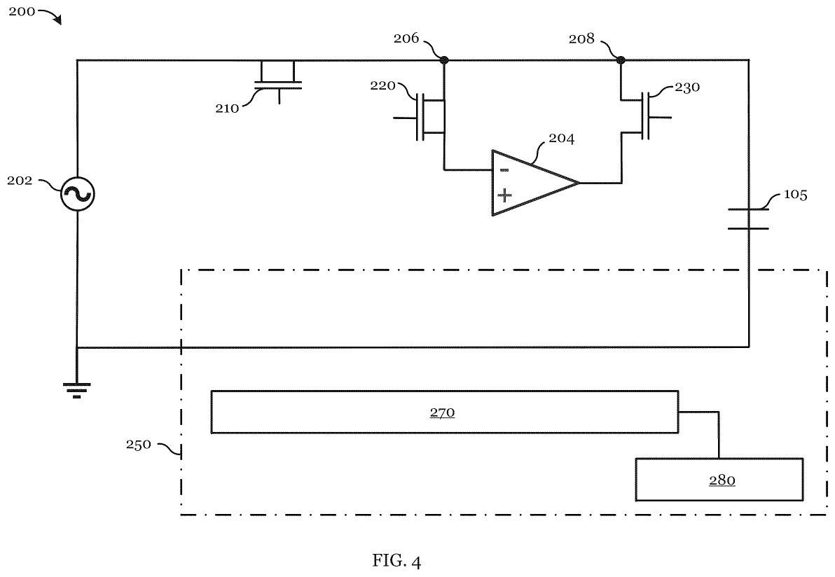

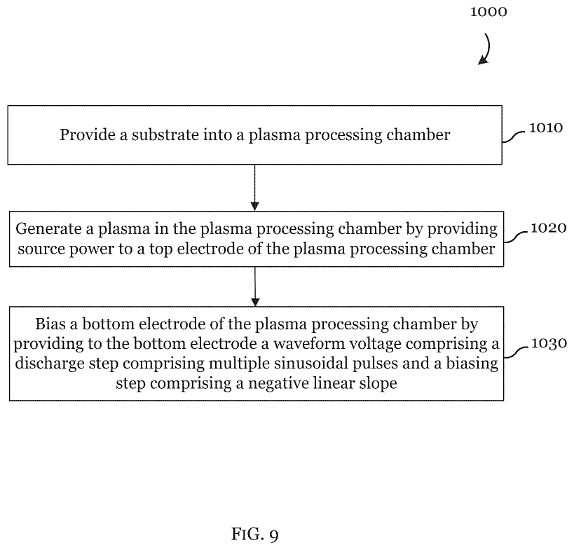

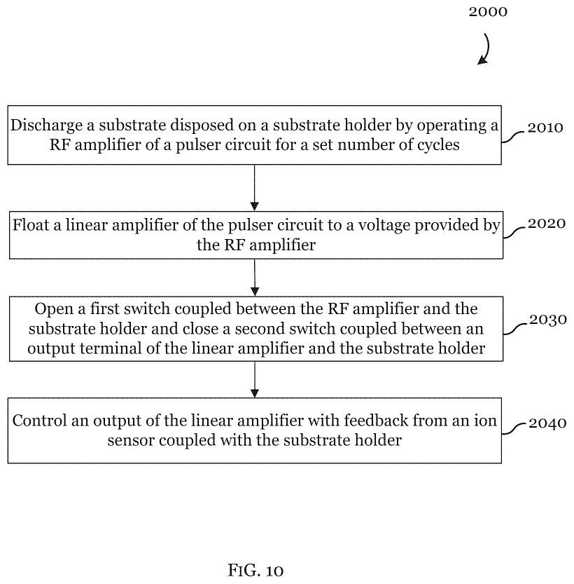

Embodiments of the disclosure are described in the context of the accompanying drawings. Embodiments of bias waveforms for biasing substrates will be described using FIGS. 1A and 1B. An embodiment of an example plasma processing system will be described using FIG. 2. Experimental results of measured ion flux and compensation current of a pulser circuit will be described using FIG. 3. An embodiment of a pulser circuit and its operation will be described using FIGS. 4 through 8. An embodiment of a method for plasma processing will be described using FIG. 9. An embodiment of a method for producing a bias waveform will be described using FIG. 10.

FIG. 1A illustrates a graph of output voltage Vₒᵤₜ versus time t for an example bias waveform for biasing a substrate during a plasma process, and FIG. 1B illustrates a graph of output voltage Vₒᵤₜ versus time t for another bias waveform approximating the tailored waveform of FIG. 1A with multiple sinusoidal pulses, in accordance with some embodiments. Approximating the bias waveform illustrated by FIG. 1A with a hybrid waveform including sinusoidal pulses and linear segments is advantageous for allowing use of a pulser circuit with technologically easily accessible components such as an RF source and a linear current amplifier.

The bias waveform of FIG. 1A includes a discharge step T₁ that comprises the voltage reversal step 10 and a biasing step T₂ that comprises the compensation step 30, with the regulation step 20 between the voltage reversal step 10 and the compensation step 30. In various embodiments, the discharge step T₁ and the biasing step T₂ have a total period of 2.5 μs, which is equivalent to a frequency of 400 kHz for the tailored waveform. The discharge step T₁ and the biasing step T₂ may have a duty cycle with a ratio of 10% to 90% for the duration of the discharge step T₁ to the duration of the biasing step T₂.

The bias waveform illustrated by FIG. 1B includes a discharge step T₃ that comprises a sinusoidal pulse step 40 and a biasing step T₄ that comprises the compensation step 60, with a transition step 50 between the sinusoidal pulse step 40 and the compensation step 60. The compensation step 60 is followed by an additional sinusoidal pulse step 40. The bias waveform illustrated by FIG. 1B approximates the bias waveform illustrated by FIG. 1A by replacing the sawtooth pulses of the voltage reversal step 10 with multiple sinusoidal pulses of the sinusoidal pulse step 40. Although FIG. 1B illustrates the sinusoidal pulse step 40 as having three sinusoidal pulses, the sinusoidal pulse step 40 may have any suitable number of sinusoidal pulses, such as two to ten sinusoidal pulses. The sinusoidal pulses may have frequencies in a range of 13 MHz to 100 MHz, such as 60 MHz. Using sinusoidal pulses in a range around, for example, 60 MHz may be advantageous by avoiding resonances with various process chamber components (e.g., heaters in the substrate heater with resonances around 400 kHz).

In various embodiments, the discharge step T₃ and the biasing step T₄ have a total period in a range of 1 μs to 10 μs, such as 2.5 μs, which is equivalent to a frequency for the tailored waveform in a range of 100 kHz to 1 GHz, such as 400 kHz. Using the multiple sinusoidal pulses in the sinusoidal pulse step 40 to approximate the voltage reversal step 10 may allow for a smaller ratio between the duration of the discharge step T₃ and the duration of the biasing step T₄, which may be advantageous for process recipes requiring increased ion flux leading to increased throughput. In some embodiments, the discharge step T₃ and the biasing step T₄ have a duty cycle such that a ratio for the duration of the discharge step T₃ to the duration of the biasing step T₄ is reduced from the industry standard of 10%:90%. Ratios approaching 2%:98% can be obtained depending on the control circuitry, and the ratio for the duration of the discharge step T₃ to the duration of the biasing step T₄ may be in a range of 2%:98% to 50%:50%.

FIG. 2 illustrates an example plasma processing system 100, in accordance with some embodiments. As illustrated in FIG. 2, the plasma processing system 100 comprises a plasma processing chamber 110 with source power excitation and substrate bias power (in other words, wafer biasing capabilities). The plasma processing chamber 110 comprises a top plate 112, a bottom plate 114, and a side wall 116. The top plate 112, bottom plate 114, and side wall 116 may be nonconductive, conductive or electrically coupled to the system ground (a reference potential).

Further in FIG. 2, a top electrode 150 is located outside the plasma processing chamber 110, positioned above a top plate 112. In various embodiments, the top electrode 150 is a conductive spiral coil electrode which may be used for inductively coupled plasma (ICP). However, any suitable top electrode 150 may be used, such as a flat plate for capacitively coupled plasma (CCP). The top electrode 150 may be coupled to a radio frequency (RF) source 165 via a matching network 167.

The matching network 167 typically includes one or more capacitors and inductors. In embodiments, the capacitors and inductors may be variable. The forward and reflected power at the matching network 167 can be measured, and the matching network 167 may be adjusted to improve impedance matching. For example, a feedback loop circuit may be used to adjust the variable capacitors and inductors.

A substrate 102 may be placed or disposed on a substrate holder 105 in the plasma processing chamber 110. In various embodiments, the substrate 102 may be a part of, or including, a semiconductor device, and may have undergone a number of steps of processing following, for example, a conventional process. The substrate 102 accordingly may comprise layers of semiconductors useful in various microelectronics. For example, the semiconductor structure may comprise the substrate 102 in which various device regions are formed.

In one or more embodiments, the substrate 102 may be a silicon wafer or a silicon-on-insulator (SOI) wafer. In certain embodiments, the substrate 102 may comprise a silicon germanium wafer, silicon carbide wafer, gallium arsenide wafer, gallium nitride wafer or other compound semiconductor. In other embodiments, the substrate 102 comprises heterogeneous layers such as silicon germanium on silicon, gallium nitride on silicon, silicon carbon on silicon, or layers of silicon on a silicon or SOI substrate. In various embodiments, the substrate 102 is patterned or embedded in other components of the semiconductor device.

In various embodiments, the plasma processing system 100 may further comprise a focus ring 154 positioned over a bottom electrode 120 to surround the substrate 102. The focus ring 154 may advantageously maintain and extend the uniformity of a plasma 160 to achieve process consistency at the edge of the substrate 102. In various embodiments, the focus ring 154 may have a width of a few centimeters. In various embodiments, there may be a gap for mechanical clearance between the circumference of the substrate 102 and the focus ring 154. In certain embodiments, the gap may be hundreds of microns to a few millimeters. In various embodiments, the focus ring 154 comprises a dielectric material with a desired dielectric constant. In certain embodiments, the focus ring 154 comprises silicon. Some examples of silicon-based focus ring comprise silicon, silicon oxide, doped silicon (e.g., boron-doped, nitrogen-doped, and phosphorous-doped), or silicon carbide. Alternatively, in some embodiments, the focus ring comprises a carbon-based material. In one or more embodiments, the focus ring 154 may comprise a metal oxide, such as aluminum oxide and zirconium oxide.

A process gas is introduced into the plasma processing chamber 110 by a gas delivery system 115. The gas delivery system 115 may comprise multiple gas flow controllers to control the flow of multiple gases into the plasma processing chamber 110. Any precursors that can create a plasma may be used, such as argon (Ar), tetrafluoromethane (CF₄), oxygen (O₂), an admixture of tetrafluoromethane and oxygen (CF₄/O₂), hexafluorobutadiene (C₄F₆), octafluorocyclobutane (C₄F₈), nitrogen (N₂), hydrogen (H₂), hydrogen bromide (HBr), the like, or any combination, or admixture thereof in any suitable ratio. In some embodiments, optional center/edge splitters may be used to independently adjust the gas flow rates at the center and edge of the substrate 102. In various embodiments, the total flow rate of the gas is in a range of 1 standard cubic centimeters per minute (sccm) to 5000 sccm, at a pressure in a range of 0.1 mTorr to 1 Torr, and/or at a temperature in a range of −200° C. to 500° C.

Further, in one embodiment, the gas delivery system 115 has a special showerhead configuration positioned at the top of the plasma processing chamber 110. For example, the gas delivery system 115 may have a showerhead configuration, covering the entirety of the substrate 102, including a plurality of appropriately spaced gas inlets. Alternatively, gas may be introduced through dedicated gas inlets of any other suitable configuration. The plasma processing chamber 110 may further be equipped with one or more sensors such as pressure monitors, gas flow monitors, and/or gas species density monitors. The sensors may be integrated as a part of the gas delivery system 115 in various embodiments.

In FIG. 2, the plasma processing chamber 110 is a vacuum chamber and may be evacuated using one or more vacuum pumps 135, such as a single stage pumping system or a multistage pumping system (e.g. a mechanical roughing pump combined with one or more turbomolecular pumps). In order to promote even gas flow during plasma processing, gas may be removed from more than one gas outlet or location in the plasma processing chamber 110 (e.g., on opposite sides of the substrate 102).

In various embodiments, the substrate holder 105 may be integrated with, or a part of, a chuck (e.g., a circular electrostatic chuck (ESC)) positioned near the bottom of the plasma processing chamber 110, and coupled to a bottom electrode 120. The surface of the chuck or the substrate holder 105 may be coated with a conductive material (e.g., a carbon-based or metal-nitride based coating). The substrate 102 may be optionally maintained at a desired temperature using a temperature sensor and a heating element coupled to a temperature controller (not shown). In certain embodiments, the temperature sensor may comprise a thermocouple, a resistance temperature detector (RTD), a thermistor, or a semiconductor based integrated circuit. The heating element may for example comprise a resistive heater in one embodiment. In addition, there may be a cooling element such as a liquid cooling system coupled to the temperature controller.

The bottom electrode 120 is coupled to a pulser circuit 200 (also referred to as a tailored waveform pulser circuit). The pulser circuit 200 provides a tailored waveform bias voltage to the bottom electrode 120 in order to accelerate ions to the surface of the substrate 102 and to attract electrons and neutralize charge accumulation from ions. The tailored waveform supplied by the pulser circuit 200 includes a discharge step comprising multiple sinusoidal pulses and a biasing step comprising a negative linear slope, as described above with respect to FIG. 1B. The pulser circuit 200 may be implemented using current and voltage sources that allow for precise control of wafer sheath voltage. This is advantageous for improving etch rate by increased material selectability and ion flux through high aspect structures. An embodiment of the pulser circuit 200 is described in detail below with respect to FIGS. 4 through 8.

An ion flux sensor 140 is coupled to the substrate holder 105 or is otherwise present inside the plasma processing chamber 110. Although FIG. 2 illustrates the ion flux sensor 140 as being on the substrate holder 105, the ion flux sensor 140 may have any suitable position in the plasma processing chamber 110. The ion flux sensor 140 may be used to measure, for example, ion energy distribution and ion angle distribution of ion flux from the plasma 160. A sensor for measuring substrate voltage could be incorporated in addition to or in tandem with the ion flux sensor 140. In various embodiments, output from the ion flux sensor 140 is used to determine by how much to adjust the output of a linear amplifier of the pulser circuit 200. The ion flux sensor 140 may be, for example, a plasma measurement system as described in U.S. patent application Ser. No. 18/490,256, which is hereby incorporated by reference herein in its entirety. However, any suitable plasma measurement system, ion flux measuring device, or the like may be used for the ion flux sensor 140.

The plasma processing system 100 further comprises a controller 170 to control plasma processing and adjust parameters in real time. In some embodiments, the controller 170 is a programmable processor, microprocessor, computer, or the like. Although the controller 170 is illustrated as a single element for illustrative purposes, the controller 170 may include additional elements or be part of a single element. The controller 170 may be programmable by instructions stored in software, firmware, hardware, or a combination thereof. The controller 170 may be coupled to the RF source 165, the matching network 167, the pulser circuit 200, the gas delivery system 115, the one or more vacuum pump(s) 135, and/or the ion flux sensor 140. The controller 170 may be configured to set, monitor, and/or control various control parameters associated with generating a plasma and delivering ions to the surface of a microelectronic workpiece (e.g., a substrate 102 such as a semiconductor wafer). Control parameters may include, but are not limited to, power level, frequency, and duty cycle (%) for the source power, the bias power, and the DC voltage, as well as phase delay between the bias RF voltage and DC voltage. Other control parameter sets may also be used. The controller 170 may also be configured to control the pulser circuit 200, such as by determining the duty cycle of discharge and biasing steps and controlling linear amplifier output of the pulser circuit 200 using feedback from the ion flux sensor 140.

The RF source 165 may be used to supply pulsed RF power or continuous wave (CW) power to sustain the plasma. In some embodiments where the plasma is generated and sustained by pulsed RF power, the operating pulse frequency range for the RF source power is 10 MHz to 100 MHz. Pulsed RF power from one or more RF power source(s) may be supplied in phase, out of phase, or with overlapping phases. While only one RF power source (in other words, the RF source 165) is illustrated in FIG. 2, more than one RF power source(s) may be used in various embodiments, for example, to provide a low frequency RF power and a high frequency RF power at the same time. In various embodiments, a RF pulsing at a kHz range may be used to power the plasma 160.

The configurations of the plasma etching system described above is for example only. In alternative embodiments, various alternative configurations may be used for a plasma processing system that incorporates a set of electromagnets. Further, microwave plasma (MW), electron cyclotron resonance (ECR), capacitively coupled plasma (CCP), multi-frequency CCP, inductively coupled plasma (ICP), or other suitable systems may be used. In various embodiments, the RF power, chamber pressure, substrate temperature, gas flow rates and other plasma process parameters may be selected in accordance with the respective process recipe.

In addition, embodiments of the present invention may be also applied to remote plasma systems as well as batch systems. For example, the substrate holder may be able to support a plurality of wafers that are spun around a central axis as they pass through different plasma zones. Accordingly, it is possible to have multiple plasma zones, for example, including a metal-containing plasma zone, metal-free plasma zone, and plasma-free zone (e.g., a purge zone).

FIG. 3 illustrates a graph of experimental results for compensation current of a pulser circuit versus measured ion flux, in accordance with some embodiments. As illustrated in FIG. 3, a linear relationship exists between the measured ion flux and the compensation current. As such, a desired ion flux can be achieved by controlling the compensation current provided by the pulser circuit.

FIGS. 4 through 8 illustrate diagrams of the pulser circuit 200 at various stages of operation while producing a tailored waveform such as illustrated above with respect to FIG. 1B, in accordance with various embodiments. The pulser circuit 200 comprises a voltage source 202, a linear amplifier 204, a first switch 210, a second switch 220, and a third switch 230. FIG. 4 illustrates the pulser circuit 200 during a sinusoidal pulse step 40 (see above, FIG. 1B). The voltage source 202 is coupled to a substrate holder 105 (see above, FIG. 2) through a first switch 210, a first node 206, and a second node 208. Although FIGS. 4 through 8 illustrate the substrate holder 105 being coupled with the pulser circuit 200, any suitable load may be used in place of the substrate holder 105.

The voltage source 202 and the substrate holder 105 are further coupled opposite the first switch 210 to a ground node. In various embodiments, the voltage source 202 is an RF source, RF amplifier, or the like. However, any suitable voltage source capable of providing sinusoidal pulses may be used for the voltage source 202. In some embodiments, the linear amplifier 204 is an operational amplifier. However, any suitable linear current amplifier device may be used for the linear amplifier 204.

In some embodiments, the first switch 210 is a high voltage MOSFET switch, such as an HTS 50-12. As an example, the first switch 210 is capable of a floated voltage greater than 15 kV and has a rise time of less than 3 nanoseconds. However, any suitable switch or transistor device may be used for the first switch 210. In various embodiments, the first switch 210 is coupled to the voltage source 202 through a drain terminal and to the first node 206 through a source terminal. However, the first switch 210 may be coupled to the voltage source 202 and the first node 206 through any suitable terminals.

A negative input terminal of the linear amplifier 204 is coupled to the first node 206 through the second switch 220. In some embodiments, the second switch 220 is a high voltage MOSFET switch as described above with respect to the first switch 210. However, any suitable switch or transistor device may be used for the second switch 220. In various embodiments, the second switch 220 is coupled to the first node 206 through a drain terminal and to the negative input terminal of the linear amplifier 204 through a source terminal. However, the second switch 220 may be coupled to the first node 206 and the negative input terminal of the linear amplifier 204 through any suitable terminals.

The output terminal of the linear amplifier 204 is coupled to the second node 208 through the third switch 230. In some embodiments, the third switch 230 is a high voltage MOSFET switch as described above with respect to the first switch 210. However, any suitable switch or transistor device may be used for the third switch 230. In various embodiments, the third switch 230 is coupled to the output terminal of the linear amplifier 204 through a drain terminal and to the second node 208 through a source terminal. However, the third switch 230 may be coupled to the output terminal of the linear amplifier 204 and the second node 208 through any suitable terminals.

The pulser circuit 200 further includes a master timing circuit 250 that is configured to provide trigger pulses to the gate terminals of the first switch 210, the second switch 220, and the third switch 230 in order to open and close the switches and thereby connect output from either the voltage source 202 or the linear amplifier 204 to the substrate holder 105. In various embodiments, the master timing circuit 250 comprises a control interface circuit 270 and a master clock circuit 280 that is coupled with it in order to provide timing pulses to the control interface circuit 270. The master timing circuit 250 may be implemented as part of the controller 170 (see above, FIG. 2), as a separate circuit from the controller 170, or as having some parts included in the controller 170 and having some parts separate from the controller 170. In some embodiments, the master timing circuit 250 is coupled to an ion flux sensor 140 (see above, FIG. 2) to receive feedback on ion energy distribution and/or ion angle distribution.

In FIG. 4, the pulser circuit 200 is operating to provide sinusoidal pulses to the substrate holder 105. As such, the first switch 210 is closed so that the voltage source 202 provides sinusoidal pulses to the substrate holder 105 for a set number of cycles in a range of, for example, two to ten cycles, such as three cycles, in order to discharge accumulated positive charge on the substrate 102. The second switch 220 is closed in order to float the linear amplifier 204 to the voltage provided by the voltage source 202. The third switch 230 is open so that output from the linear amplifier 204 is not provided to the substrate holder 105.

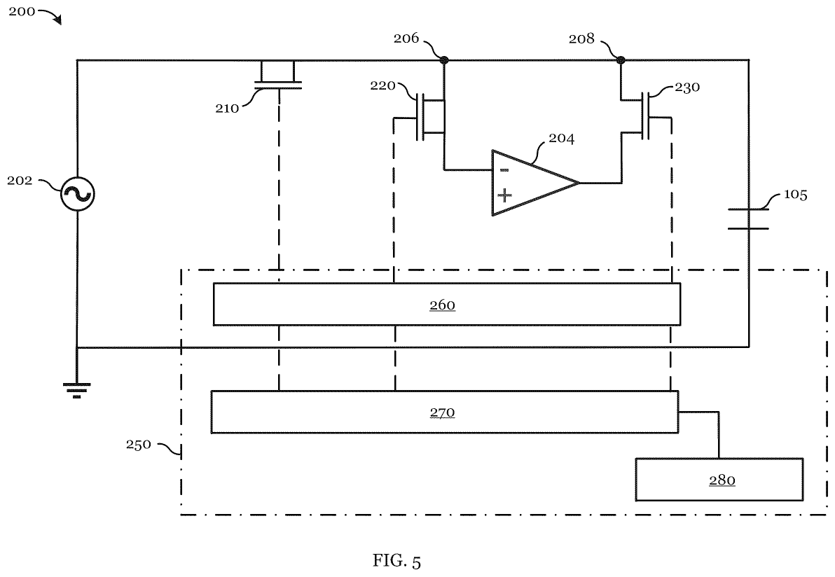

Next, as illustrated by FIG. 5, the control interface circuit 270 sends galvanically isolated signals (also referred to as trigger pulses) through an electronic control isolation circuit 260 to activate the first switch 210, the second switch 220, and the third switch 230. The electronic control isolation circuit 260 may be part of the master timing circuit 250 and is configured to galvanically isolate the trigger pulses from the control interface circuit 270 to respective gate terminals of the first switch 210, the second switch 220, and the third switch 230.

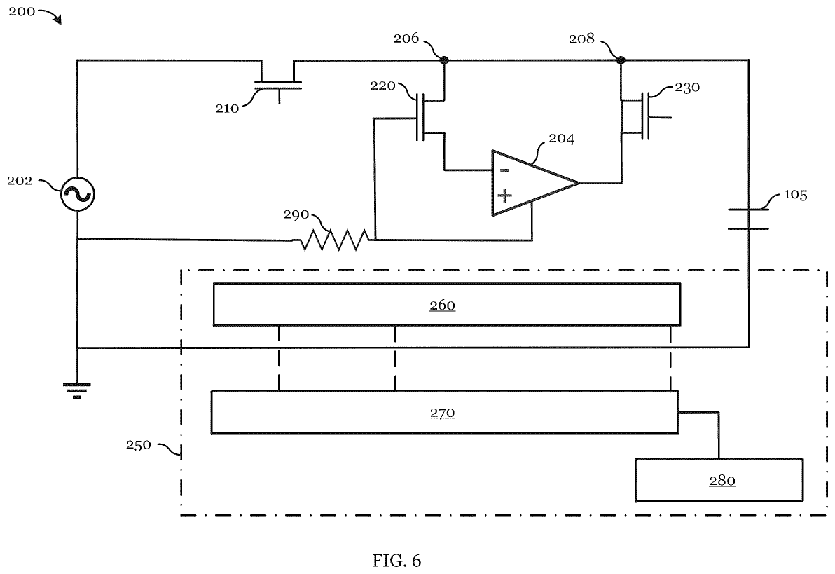

FIG. 6, following from FIG. 5, corresponds to the transition step 50 as described above with respect to FIG. 1B. In FIG. 6, the first switch 210 and the second switch 220 are opened and the third switch 230 is closed by the galvanically isolated signals from the master timing circuit 250, as described above with respect to FIG. 5. The gate terminal of the second switch 220 and the common terminal of the linear amplifier 204 are coupled to a ground terminal through a high value resistor 290, which allows for a very small amount of the voltage and current present in the circuit to bleed through to ground. Once the biasing of the linear amplifier 204 is removed, it is beneficial for the common terminal of the linear amplifier 204 to have an electrical reference. The high value resistor 290 allows coupling to ground but only allows small amount of current to reach ground. This lets the common terminal of the linear amplifier 204 to lose the original bias voltage but by a certain constant amount. However, the linear amplifier 204 can be configured to compensate for the constant amount of voltage loss. In some embodiments, the high value resistor 290 has a resistance in a range of 1 MΩ to 100 MΩ. With the third switch 230 closed, the output of the linear amplifier 204 is coupled to the substrate holder 105.

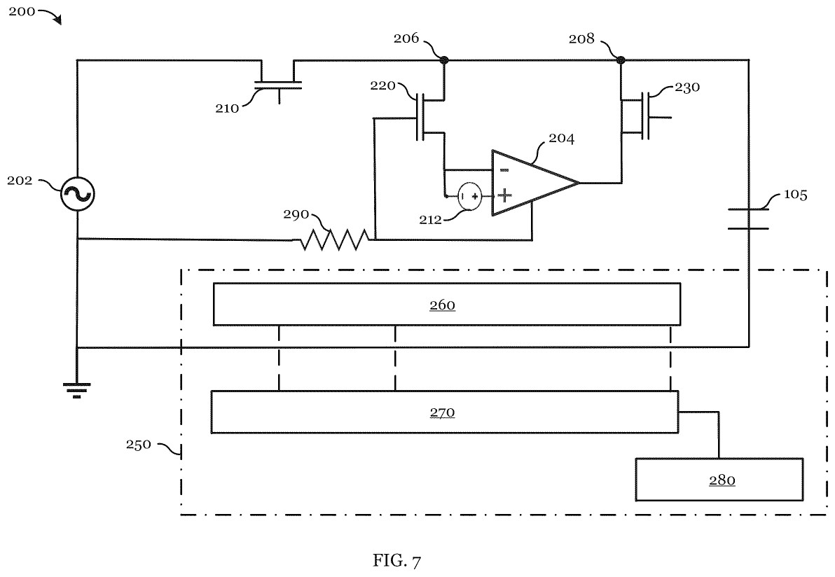

Next, in FIG. 7, which corresponds to the compensation step 60 as described above with respect to FIG. 1B, the linear amplifier 204 is activated and begins supplying a compensation current to the substrate holder 105. This produces the negative linear slope of the tailored waveform during the compensation step 60 (see above, FIG. 1B), allowing the substrate holder 105 to maintain a constant voltage during a plasma process as it accumulates positive ions. In some embodiments, the linear amplifier 204 is activated with a DC voltage source 212 coupled to the positive input terminal of the linear amplifier 204 while the negative input terminal retains most of the voltage previously supplied by the voltage source 202 due to inclusion of the high value resistor 290 to ground. The linear amplifier 204 may be controlled by feedback from an ion flux sensor 140 (see above, FIG. 2), which may be coupled to the controller 170 (see above, FIG. 2) and/or the master timing circuit 250 to thereby control the DC voltage source 212 and compensate for loss through the high value resistor 290. In some embodiments, a current meter is coupled to the output of the linear amplifier 204 to provide feedback back to the linear amplifier 204.

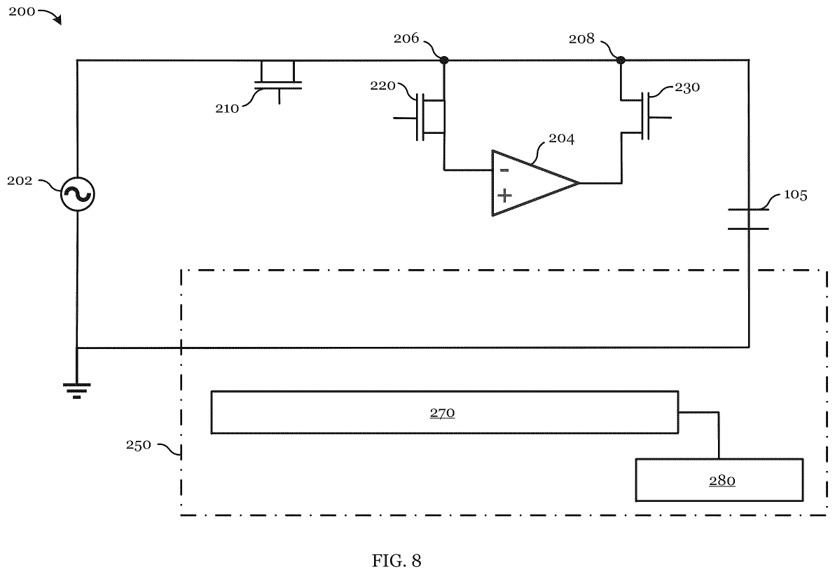

FIG. 8, following from FIG. 7, corresponds to the next sinusoidal pulse step 40 (see above, FIG. 1B). The master timing circuit 250 sends galvanically isolated signals (also referred to as galvanically isolated pulses) to close the first switch 210 and the second switch 220 and to open the third switch 230. This returns the pulser circuit 200 to its state in FIG. 4 with the voltage source 202 providing sinusoidal pulses to the substrate holder 105 and the linear amplifier 204 not providing output to the substrate holder 105. The biasing and discharge steps of FIGS. 4 through 7 may be repeated for any suitable number of cycles, such as to perform a plasma process (e.g., an atomic layer etching (ALE) process).

FIG. 9 illustrates a process flow chart diagram of a method 1000 for plasma processing, in accordance with some embodiments. In step 1010, a substrate is provided into a plasma processing chamber, as described above with respect to FIG. 2. In step 1020, a plasma is generated in the plasma processing chamber by providing source power to a top electrode of the plasma processing chamber, as described above with respect to FIG. 2. In step 1030, a bottom electrode of the plasma processing chamber is biased by providing a waveform voltage to the bottom electrode, as described above with respect to FIGS. 1B and 2. The waveform voltage comprises a discharge step comprising multiple sinusoidal pulses and a biasing step comprising a negative linear slope.

FIG. 10 illustrates a process flow chart diagram of a method 2000 for producing a bias waveform, in accordance with some embodiments. In step 2010, a substrate disposed on a substrate holder is discharged by operating a radio frequency (RF) amplifier of a pulser circuit for a set number of cycles, as described above with respect to FIG. 4. The RF amplifier is coupled with the substrate holder. In step 2020, a linear amplifier of the pulser circuit is floated to a voltage provided by the RF amplifier, as described above with respect to FIG. 4.

In step 2030, a first switch coupled between the RF amplifier and the substrate holder is opened and second switch coupled between an output terminal of the linear amplifier and the substrate holder is closed, as described above with respect to FIGS. 5 and 6. In step 2040, an output of the linear amplifier is controlled with feedback from an ion flux sensor, as described above with respect to FIG. 7. The ion flux sensor is coupled with the substrate holder.

Example embodiments of the disclosure are summarized here. Other embodiments can also be understood from the entirety of the specification as well as the claims filed herein.

Example 1. A method for plasma processing, the method including: providing a substrate into a plasma processing chamber; generating a plasma in the plasma processing chamber by providing source power to a top electrode of the plasma processing chamber; and biasing a bottom electrode of the plasma processing chamber by providing a waveform voltage to the bottom electrode, the waveform voltage including: a discharge step including multiple sinusoidal pulses; and a biasing step including a negative linear slope.

Example 2. The method of example 1, where the discharge step includes two to ten sinusoidal pulses.

Example 3. The method of one of examples 1 or 2, where the multiple sinusoidal pulses have a frequency in a range of 13 MHz to 100 MHz.

Example 4. The method of one of examples 1 to 3, where a ratio of a duration of the discharge step to a duration of the biasing step is in a range of 2%:98% to 50%:50%.

Example 5. The method of one of examples 1 to 4, where the waveform voltage has a frequency in a range of 100 kHz to 1 GHz.

Example 6. The method of one of examples 1 to 5, where the multiple sinusoidal pulses are generated by an RF amplifier, the RF amplifier being coupled with the bottom electrode.

Example 7. The method one of examples 1 to 6, where the negative linear slope of the biasing step is generated by a linear amplifier, the linear amplifier being coupled with the bottom electrode.

Example 8. The method of one of examples 1 to 7, where the negative linear slope of the biasing step is controlled by feedback from an ion flux sensor, the ion flux sensor being in the plasma processing chamber.

Example 9. A method for producing a bias waveform, the method including: discharging a substrate disposed on a substrate holder by operating a radio frequency (RF) amplifier of a pulser circuit for a set number of cycles, the RF amplifier being coupled with the substrate holder; floating a linear amplifier of the pulser circuit to a voltage provided by the RF amplifier; opening a first switch coupled between the RF amplifier and the substrate holder and closing a second switch coupled between an output terminal of the linear amplifier and the substrate holder; and controlling an output of the linear amplifier with feedback from an ion flux sensor, the ion flux sensor being coupled with the substrate holder.

Example 10. The method of example 9, where the first switch and the second switch are MOSFETs.

Example 11. The method of one of examples 9 or 10, further including opening the second switch and closing the first switch after completing a biasing step by supplying the output of the linear amplifier to the substrate holder.

Example 12. The method of one of examples 9 to 11, where the first switch and the second switch are controlled by galvanically isolated pulses from a master timing circuit.

Example 13. The method of one of examples 9 to 12, where the set number of cycles is three.

Example 14. A pulser circuit including: a radio frequency (RF) amplifier; a first switch, a first terminal of the first switch being coupled to the RF amplifier, a second terminal of the first switch being coupled with a substrate holder through a first node and a second node; a linear amplifier including a negative input terminal, a positive input terminal, and an output terminal, the negative input terminal being coupled through a second switch to the first node, the output terminal being coupled through a third switch to the second node; and a master timing circuit configured to open and close the first switch, the second switch, and the third switch.

Example 15. The pulser circuit of example 14, where the positive input terminal of the linear amplifier is coupled to a DC voltage source.

Example 16. The pulser circuit of one of examples 14 or 15, where the first switch, the second switch, and the third switch are high voltage MOSFETs.

Example 17. The pulser circuit of example 16, where the first switch, the second switch, and the third switch have floated voltages greater than 15 kV.

Example 18. The pulser circuit of one of examples 16 or 17, where the first switch, the second switch, and the third switch have a rise time of less than 3 nanoseconds.

Example 19. The pulser circuit of one of examples 14 to 18, where the master timing circuit includes a control interface circuit coupled with an electronic control isolation circuit, the electronic control isolation circuit being configured to activate the first switch, the second switch, and the third switch with respective galvanically isolated signals.

Example 20. The pulser circuit of one of examples 14 to 19, further including a resistor coupling a ground terminal with a gate terminal of the second switch and a linear amplifier common terminal.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for plasma processing, the method comprising:
providing a substrate into a plasma processing chamber;
generating a plasma in the plasma processing chamber by providing source power to a top electrode of the plasma processing chamber; and
biasing a bottom electrode of the plasma processing chamber by providing a waveform voltage to the bottom electrode, the waveform voltage comprising:
a discharge step comprising multiple sinusoidal pulses; and
a biasing step comprising a negative linear slope.

2. The method of claim 1, wherein the discharge step comprises two to ten sinusoidal pulses.

3. The method of claim 1, wherein the multiple sinusoidal pulses have a frequency in a range of 13 MHz to 100 MHz.

4. The method of claim 1, wherein a ratio of a duration of the discharge step to a duration of the biasing step is in a range of 2%:98% to 50%:50%.

5. The method of claim 1, wherein the waveform voltage has a frequency in a range of 100 kHz to 1 GHz.

6. The method of claim 1, wherein the multiple sinusoidal pulses are generated by an RF amplifier, the RF amplifier being coupled with the bottom electrode.

7. The method of claim 1, wherein the negative linear slope of the biasing step is generated by a linear amplifier, the linear amplifier being coupled with the bottom electrode.

8. The method of claim 1, wherein the negative linear slope of the biasing step is controlled by feedback from an ion flux sensor, the ion flux sensor being in the plasma processing chamber.

9. A method for producing a bias waveform, the method comprising:
discharging a substrate disposed on a substrate holder by operating a radio frequency (RF) amplifier of a pulser circuit for a set number of cycles, the RF amplifier being coupled with the substrate holder;
floating a linear amplifier of the pulser circuit to a voltage provided by the RF amplifier;
opening a first switch coupled between the RF amplifier and the substrate holder and closing a second switch coupled between an output terminal of the linear amplifier and the substrate holder; and
controlling an output of the linear amplifier with feedback from an ion flux sensor, the ion flux sensor being coupled with the substrate holder.

10. The method of claim 9, wherein the first switch and the second switch are MOSFETs.

11. The method of claim 9, further comprising opening the second switch and closing the first switch after completing a biasing step by supplying the output of the linear amplifier to the substrate holder.

12. The method of claim 9, wherein the first switch and the second switch are controlled by galvanically isolated pulses from a master timing circuit.

13. The method of claim 9, wherein the set number of cycles is three.

14. A pulser circuit comprising:
a radio frequency (RF) amplifier;
a first switch, a first terminal of the first switch being coupled to the RF amplifier, a second terminal of the first switch being coupled with a substrate holder through a first node and a second node;
a linear amplifier comprising a negative input terminal, a positive input terminal, and an output terminal, the negative input terminal being coupled through a second switch to the first node, the output terminal being coupled through a third switch to the second node; and
a master timing circuit configured to open and close the first switch, the second switch, and the third switch.

15. The pulser circuit of claim 14, wherein the positive input terminal of the linear amplifier is coupled to a DC voltage source.

16. The pulser circuit of claim 14, wherein the first switch, the second switch, and the third switch are high voltage MOSFETs.

17. The pulser circuit of claim 16, wherein the first switch, the second switch, and the third switch have floated voltages greater than 15 kV.

18. The pulser circuit of claim 16, wherein the first switch, the second switch, and the third switch have a rise time of less than 3 nanoseconds.

19. The pulser circuit of claim 14, wherein the master timing circuit comprises a control interface circuit coupled with an electronic control isolation circuit, the electronic control isolation circuit being configured to activate the first switch, the second switch, and the third switch with respective galvanically isolated signals.

20. The pulser circuit of claim 14, further comprising a resistor coupling a ground terminal with a gate terminal of the second switch and a linear amplifier common terminal.
